(19) United States
(12) Patent Application Publication
(10) Pub. No.: US 2014/0273461 A1
(43) Pub. Date: Sep. 18, 2014

(54) CARBON FILM HARDMASK STRESS REDUCTION BY HYDROGEN ION IMPLANTATION

(71) Applicant: APPLIED MATERIALS, INC., Santa Clara, CA (US)

(72) Inventors: Kwangduk Douglas LEE, Redwood City, CA (US); Martin Jay SEAMONS, San Jose, CA (US); Matthew D. SCOTNEY-CASTLE, Morgan Hill, CA (US); Martin A. HILKENE, Gilroy, CA (US); Ludovic GODET, Boston, MA (US)

(73) Assignee: APPLIED MATERIALS, INC., Santa Clara, CA (US)

(21) Appl. No.: 14/201,700

(22) Filed: Mar. 7, 2014

Related U.S. Application Data
(60) Provisional application No. 61/792,378, filed on Mar. 15, 2013.

(51) Int. Cl. H01L 21/314; H01L 21/311

(52) U.S. Cl. CPC H01L 21/3146; H01L 21/31111
USPC 438/694; 438/778

(57) ABSTRACT

Methods for forming a hydrogen implanted amorphous carbon layer with desired film mechanical strength as well as optical film properties are provided. In one embodiment, a method of a hydrogen implanted amorphous carbon layer includes providing a substrate having a material layer disposed thereon, forming an amorphous carbon layer on the material layer, and ion implanting hydrogen ions from a hydrogen containing gas into the amorphous carbon layer to form a hydrogen implanted amorphous carbon layer.

### CROSS-REFERENCE TO RELATED APPLICATION

This application claims benefit of U.S. Provisional Application Ser. No. 61/792,378 filed Mar. 15, 2013 (Attorney Docket No. EPIS/20405L), which is incorporated by reference in its entirety.

### BACKGROUND

1. Field of the Invention

The present invention relates to the fabrication of integrated circuits and to a process for forming a hardmask layer with high etching selectivity and good mechanical strength on a substrate. More specifically, the invention relates to a process for manufacturing an amorphous carbon layer with high etching selectivity, good mechanical strength and low stress on a substrate for semiconductor applications.

2. Description of the Background Art

Integrated circuits have evolved into complex devices that can include millions of transistors, capacitors and resistors on a single chip. The evolution of chip designs continually requires faster circuitry and greater circuit density. The demands for faster circuits with greater circuit densities impose corresponding demands on the materials used to fabricate such integrated circuits. In particular, as the dimensions of integrated circuit components are reduced to the sub-micron scale, it is now necessary to use low resistivity conductive materials (e.g., copper) as well as low dielectric constant insulating materials (dielectric constant less than about 4) to obtain suitable electrical performance from such components.

The demands for greater integrated circuit densities also impose demands on the process sequences used in the manufacture of integrated circuit components. For example, in process sequences that use conventional photo lithographic techniques, a layer of energy sensitive resist is formed over a stack of material layers disposed on a substrate. The energy sensitive resist layer is exposed to an image of a pattern to form a photoresist mask. Thereafter, the mask pattern is transferred to one or more of the material layers of the stack using an etch process. The chemical etchant used in the etch process is selected to have a greater etch selectivity for the material layers of the stack than for the mask of energy sensitive resist. That is, the chemical etchant etches the one or more layers of the material stack at a rate much faster than the energy sensitive resist. The etch selectivity to the one or more material layers of the stack over the resist prevents the energy sensitive resist from being consumed prior to completion of the pattern transfer. Thus, a highly selective etchant enhances accurate pattern transfer.

As the geometry limits of the structures used to form semiconductor devices are pushed against technology limits, the need for accurate pattern transfer for the manufacture of structures having small critical dimensions and high aspect ratios has become increasingly difficult. For example, the thickness of the energy sensitive resist has been reduced in order to control pattern resolution. Such thin resist layers (e.g., less than about 2000 Å) can be insufficient to mask underlying material layers during the pattern transfer step due to attack by the chemical etchant. An intermediate layer (e.g., silicon oxynitride, silicon carbine or carbon film), called a hardmask layer, is often used between the energy sensitive resist layer and the underlying material layers to facilitate pattern transfer because of its greater resistance to chemical etchants. When etching materials to form structures having aspect ratios greater than about 5:1 and/or critical dimensional less than about 50 nm, the hardmask layer utilized to transfer patterns to the materials is exposed to aggressive etchants for a significant period of time. After a long period of exposure to the aggressive etchants, the hardmask layer without sufficient etching resistance may be changed, resulting in inaccurate pattern transfer and loss of dimensional control.

Furthermore, the similarity of the materials selected for the hardmask layer and the adjacent layers disposed in the film stack may also result in similar etch properties therebetween, thereby resulting in poor selectivity during etching. Poor selectivity between the hardmask layer and adjacent layers may result in non-uniform, tapered and deformed profile of the hardmask layer, thereby leading to poor pattern transfer and failure of accurate structure dimension control.

Additionally, stress in the deposited film and/or hardmask layer may also result in stress induced line edge bending and/or line breakage. Overly high stress of the hardmask layer may cause substrate bow that result in substrate chucking/dechucking problems. Furthermore, high stress of the hardmask layer also result in compressive film structure of the hardmask layer which may lead to depth-of-focus problem during a lithography exposure process, thereby adversely affecting pattern transfer accuracy in the subsequent processes.

Therefore, there is a need in the art for an improved hardmask layer with desired film properties for subsequent lithography and etching processes.

### SUMMARY

Methods for forming a hydrogen implanted amorphous carbon layer with desired film mechanical strength as well as optical film properties are provided. In one embodiment, a method of for forming a hydrogen implanted amorphous carbon layer includes providing a substrate having a material layer disposed thereon, forming an amorphous carbon layer on the material layer, and ion implanting hydrogen ions from a hydrogen containing gas into the amorphous carbon layer to form a hydrogen implanted amorphous carbon layer.

In another embodiment, a method of hydrogen implanted amorphous carbon layer includes providing a substrate having a material layer disposed thereon, forming an amorphous carbon layer on the material layer, and ion implanting hydrogen ions from a hydrogen containing gas into the amorphous carbon layer to form a hydrogen implanted amorphous carbon layer, wherein the hydrogen implanted amorphous carbon layer has a stress between about 800 mega-pascal (MPa) compressive and about 100 mega-pascal (MPa) compressive.

In yet another embodiment, a method of treating hydrogen implanted amorphous carbon layer includes providing a substrate having a material layer disposed thereon, (b) forming an amorphous carbon layer on the material layer, ion implanting hydrogen ions from a hydrogen containing gas into the amorphous carbon layer to form a hydrogen implanted amorphous carbon layer, and etching the material layer using the hydrogen implanted amorphous carbon layer as a hardmask layer.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts one embodiment of a plasma immersion ion implantation tool suitable for practicing at least one embodiment of the present invention;

FIG. 2 depicts a schematic illustration of a deposition apparatus in which a plasma immersion ion implantation technique can be used to practice embodiments of the invention;

FIG. 3 depicts a flow process diagram of one embodiment of a film formation process;

FIGS. 4A-4C depict a sequence of schematic cross-sectional views of a substrate structure incorporating an amorphous carbon layer formed on a substrate according to the method of FIG. 3; and

FIGS. 5A-5E depict a sequence of schematic cross-sectional views of a substrate structure incorporating an amorphous carbon layer formed on a substrate according to another embodiment of the invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the present invention provide methods for forming a hydrogen implanted amorphous carbon layer with desired film properties, such as film transparency, mechanical strength and low stress. In one embodiment, the amorphous carbon layer is suitable for use as a hardmask layer. The amorphous carbon layer with desired film properties may be obtained by ion implanting hydrogen elements into an amorphous carbon layer. The hydrogen elements implanted into the amorphous carbon layer may alter the bonding structure of the carbon elements networked in the amorphous carbon layer so as to maintain low stress level in the resultant amorphous carbon layer while maintaining film density within a desired range. The implanted amorphous carbon layer has optical film properties, such as a desired range of refraction index (n) and absorption coefficient (k), that are advantageous for photolithographic patterning processes, and other film properties remain substantially unchanged after the hydrogen implantation process.

FIG. 1 depicts one embodiment of a plasma immersion ion implantation chamber (i.e., processing chamber 100) suitable for implanting hydrogen elements into an amorphous carbon layer in accordance with at least one embodiment of the present invention. The processing chamber 100 of FIG. 1 is useful for performing plasma immersion ion implantation procedures, but may also be used to shower a substrate with energetic ions to gently penetrate ions into the substrate. The processing chamber 100 includes a chamber body 102 having a bottom 124, a top 126, and side walls 122 enclosing a process region 104. A substrate support assembly 128 is supported from the bottom 124 of the chamber body 102 and is adapted to receive a substrate 151 for processing. In one embodiment, the substrate support assembly 128 may include an embedded heater element or cooling element (not shown) suitable for controlling the temperature of the substrate 151 supported on the substrate support assembly 128. In one embodiment, the temperature of the substrate support assembly 128 may be controlled to prevent the substrate 151 from over heat during the plasma immersion ion implantation process so as to maintain the substrate 151 at a substantially constant temperature during the plasma immersion ion implantation process. The temperature of the substrate support assembly 128 may be controlled between about 10 degrees Celsius to about 200 degrees Celsius.

A gas distribution plate 130 (shown in phantom) is coupled to the top 126 of the chamber body 102 facing the substrate support assembly 128. A pumping port 132 is defined in the chamber body 102 and coupled to a vacuum pump 134. The vacuum pump 134 is coupled through a throttle valve 136 to the pumping port 132. A process gas source 152 is coupled to the gas distribution plate 130 to supply gaseous precursor compounds for processes performed on the substrate 151.

The chamber 100 depicted in FIG. 1 further includes a plasma source 190. The plasma source 190 includes a pair of separate external reentrant conduits 140, 140′ mounted on the outside of the top 126 of the chamber body 102 disposed transverse or orthogonal to one another. The first external conduit 140 has a first end 140a coupled to an opening 198 formed in the top 126 and is in communication with a first side of the process region 104 in the chamber body 102. A second end 140b has an opening 196 coupled to the top 126 and is in communication with a second side of the process region 104. The second external reentrant conduit 140b has a first end 140a′ having an opening 194 coupled to the top 126 and in communication with a third side of the process region 104. A second end 140b′ having an opening 192 of the second external reentrant conduit 140b is coupled to the top 126 and is in communication with a fourth side of the process region 104. In one embodiment, the first and second external reentrant conduits 140, 140′ are configured to be orthogonal to one another, thereby providing the two ends 140a, 140a′, 140b, 140b′ of each external reentrant conduits 140, 140′ orientated at about 90 degree intervals around the periphery of the top 126 of the chamber body 102. The orthogonal configuration of the external reentrant conduits 140, 140′ allows a plasma source distributed uniformly across the process region 104. It is contemplated that the first and second external reentrant conduits 140, 140′ may have other configurations utilized to control plasma distribution in the process region 104.

Magnetically permeable torroidal cores 142, 142′ surround a portion of a corresponding one of the external reentrant conduits 140, 140′. The conductive coils 144, 144′ are coupled to respective RF power sources 146, 146′ through respective impedance match circuits or elements 148, 148′. Each external reentrant conduits 140, 140′ is a hollow conductive tube interrupted by an insulating annular ring 150, 150′ respectively that interrupts an otherwise continuous electrical path between the two ends 140a, 140b (and 140a′, 104b′) of the respective external reentrant conduits 140, 140′. Ion energy at the substrate surface is controlled by an RF bias generator 154 coupled to the substrate support assembly 128 through an impedance match circuit or element 156.

Process gases including gaseous compounds supplied from the process gas source 152 are introduced through the overhead gas distribution plate 130 into the process region 104. RF power source 146 is coupled from the power applicators, i.e., core and coil, 142, 144 to gases supplied in the conduit 140, which creates a circulating plasma current in a first closed torroidal path power source 146′ may be coupled from the other power applicators, i.e., core and coil, 142′, 144′ to gases in the second conduit 140′, which creates a circulating plasma current in a second closed torroidal path transverse (e.g., orthogonal) to the first torroidal path. The second torroidal path includes the second external reentrant conduit 140′ and the process region 104. The plasma currents in each of the paths oscillate (e.g., reverse direction) at the frequencies of the respective RF power sources 146, 146′, which may be the same or slightly offset from one another.

In operation, a process gas mixture is provided to the chamber from the process gas source 152. Depending on the embodiment, the process gas mixture may comprise inert and/or reactive gases to be ionized and directed toward the substrate 151. Virtually any gas that may be easily ionized can be used in the chamber 100 to practice embodiments of the invention. Some inert gases that may be used include helium, argon, neon, krypton, and xenon. Reactive or reactable gases that may be used include nitrogen containing gases, halogen containing gas, hydrogen containing gases, oxygen containing gases, carbon containing gases, and combinations thereof. In some embodiments, nitrogen gas, hydrogen gas, oxygen gas, and combinations thereof may be used. In other embodiments, ammonia and its derivatives, analogues, and homologues, may be used, or hydrocarbons such as methane or ethane may be used. Any substance that may be readily vaporized, and that does not deposit a material substantially identical to the magnetically susceptible layer of the substrate, may be used to modify its magnetic properties through bombardment or plasma immersion ion implantation.

The power of each RF power source 146, 146′ is operated so that their combined effect efficiently dissociates the process gases supplied from the process gas source 152 and produces a desired ion flux at the surface of the substrate 151. The power of the RF bias generator 154 is controlled at a selected level at which the ion energy dissociated from the process gases may be accelerated toward the substrate surface and implanted at a desired depth below the top surface of the substrate 151 in a desired ion concentration. For example, with relatively low RF power of about 100 W would give ion energy of about 200 eV. Dissociated ions with low ion energy may be implanted at a shallow depth between about 1 Å and about 500 Å from the substrate surface. Alternatively, high bias power of about 5000 W would give ion energy of about 6 keV. The dissociated ions with high ion energy provided and generated from high RF bias power, such as higher than about 100 eV, may be implanted into the substrate having a depth substantially over 500 Å depth from the substrate surface. In one embodiment, the bias RF power supplied to the chamber may be between about 100 watts and about 7000 watts, which equates to an ion energy between about 100 eV and about 7 keV.

The combination of the controlled RF plasma source power and RF plasma bias power dissociates electrons and ions in the gas mixture, imparts a desired momentum to the ions, and generates a desired ion distribution in the processing chamber 100. The ions are biased and driven toward the substrate surface, thereby implanting ions into the substrate in a desired ion concentration, distribution and depth from the substrate surface. In some embodiments, ions may be implanted at a concentration between about 10¹⁵ atoms/cm³ and about 10²³ atoms/cm³ at a depth ranging from about 5 nm to about 500 nm, depending on the thickness of the material layer disposed on the substrate 151.

Plasma immersion implanting ions deep in the material layer disposed on a substrate may cause bonding structure change in the implanted area. The degree of change may be selected by tuning the depth of the implant. The size of ion being implanted will also affect the energy needed to implant ions to a given depth. For example, helium ions implanted into a material layer at an average energy of about 200 eV will change film properties of the material layer by about 20% to about 50%, and argon ions implanted at an average energy of about 1,000 eV will demagnetize and/or change film properties the material layer by about 50% to about 80%, comparatively.

It is noted that the ions provided in a plasma immersion ion implantation process, as described herein, are generated from a plasma formed by applying a high voltage RF or any other forms of EM field (microwave or DC) to a processing chamber. The plasma dissociated ions are then biased toward the substrate surface and implanted into a certain desired depth from the substrate surface.

It is noted that a conventional ion implantation processing chamber may also utilized to practice the embodiments of the present invention. Conventional ion implantation processing chamber utilizing ion guns or ion beams accelerates a majority of ions up to a certain energy resulting in implanting accelerated ions into a certain deeper region of the substrate, as compared to the ions implanted by the plasma immersion ion implantation process. The ions provided in the plasma immersion ion implantation process do not generally have a beam-like energy distribution as the ions in conventional beamliners. However, under suitable adjustment of process parameters, ion implantation performance from the plasma immersion ion implantation process and the conventional ion beam implanataion process may have similar results to have the desired ions implanted into a material layer with desired profile and distribution. In most of the embodiments, the higher energy required from the conventional ion gun (or an ion beam) ion implantation process can provide ions with higher implantation energy to penetrate into a deeper region from the substrate surface. In contrast, the plasma immersion ion implantation process utilizing RF power to plasma dissociate ions for implanting requires less energy to initiate the plasma immersion ion implantation process so that the ions generated from the plasma can be implanted into a relatively shadow depth from the substrate surface.

FIG. 2 is a schematic representation of a substrate processing system 232 that can be used to perform amorphous carbon layer deposition in accordance with embodiments of the present invention. Other examples of systems that may be used to practice the invention include CENTURA®, PRECISION 5000® and PRODUCER® deposition systems, all available from Applied Materials Inc., Santa Clara, Calif. It is contemplated that other processing system, including those available from other manufacturers, may be adapted to practice the invention.

The processing system 232 includes a process chamber 200 coupled to a gas panel 230 and a controller 210. The process chamber 200 generally includes a top 224, a side 201 and a bottom wall 222 that define an interior volume 226. A support pedestal 250 is provided in the interior volume 226 of the chamber 200. The pedestal 250 may be fabricated from aluminum, ceramic, and other suitable materials. In one embodiment, the pedestal 250 may be fabricated from a ceramic material, such as aluminum nitride, which is a material suitable for use in a high temperature environment, such as a plasma process environment, without causing thermal damage to the pedestal 250. The pedestal 250 may be moved in a vertical direction inside the chamber 200 using a lift mechanism (not shown).

The pedestal 250 may include an embedded heater element 270 suitable for controlling the temperature of a substrate 151 supported on the pedestal 250. In one embodiment, the pedestal 250 may be resistively heated by applying an electric current from a power supply 206 to the heater element 270. In one embodiment, the heater element 270 may be made of a nickel-chromium wire encapsulated in a nickel-iron-chromium alloy (e.g., INCOLOY®) sheath tube. The electric current supplied from the power supply 206 is regulated by the controller 210 to control the heat generated by the heater element 270, thereby maintaining the substrate 151 and the pedestal 250 at a substantially constant temperature during film deposition. The supplied electric current may be adjusted to selectively control the temperature of the pedestal 250 between about 100 degrees Celsius to about 780 degrees Celsius, such as greater than 500 degrees Celsius.

The substrate support pedestal 250 comprises at least one clamping electrode 239 for retaining the substrate 151 below the showerhead assembly 220. The clamping electrode 239 is driven by a chucking power source 204 to develop an electrostatic force that holds the substrate support pedestal 250 to the substrate support pedestal surface, as is conventionally known. Alternatively, the substrate 151 may be retained to the substrate support pedestal 250 by clamping, vacuum or gravity.

A temperature sensor 272, such as a thermocouple, may be embedded in the support pedestal 250 to monitor the temperature of the pedestal 250 in a conventional manner. The measured temperature is used by the controller 210 to control the power supplied to the heating element 270 to maintain the substrate 151 at a desired temperature.

A vacuum pump 202 is coupled to a port formed in the walls of the chamber 200. The vacuum pump 202 is used to maintain a desired gas pressure in the process chamber 200. The vacuum pump 202 also evacuates post-processing gases and by-products of the process from the chamber 200.

A showerhead 220 having a plurality of apertures 228 is coupled to the top 224 of the process chamber 200 above the substrate support pedestal 250. The apertures 228 of the showerhead 220 are utilized to introduce process gases into the chamber 200. The apertures 228 may have different sizes, number, distributions, shape, design, and diameters to facilitate the flow of the various process gases for different process requirements. The showerhead 220 is connected to the gas panel 230 that allows various gases to supply to the interior volume 226 during process. A plasma is formed from the process gas mixture exiting the showerhead 220 to enhance thermal decomposition of the process gases resulting in the deposition of material on a surface 291 of the substrate 151.

The showerhead 220 and substrate support pedestal 250 may be configured as a pair of spaced apart electrodes in the interior volume 226. One or more RF sources 240 provide a bias potential through a matching network 238 to the showerhead 220 to facilitate generation of a plasma between the showerhead 220 and the pedestal 250. Alternatively, the RF power sources 240 and matching network 238 may be coupled to the showerhead 220, substrate pedestal 250, or coupled to both the showerhead 220 and the substrate pedestal 250, or coupled to an antenna (not shown) disposed exterior to the chamber 200. In one embodiment, the RF sources 240 may provide between about 500 Watts and about 3000 Watts at a frequency of about 30 kHz to about 13.6 MHz.

Optionally, an ion implantation device 251 may be disposed in the processing system 232 to implant ions into the substrate 151 when needed. The ion implantation device 251 may include coils or magnetic wires 252 may be disposed above the chamber 200 to assist generate plasma ion implantation energy to assist driving ions into the substrate 151. The coils or magnetic wires 252 is coupled through a matching network 290 to a plasma power source 292, which is typically capable of producing up to about 3000 W at a tunable frequency in a range from about 50 kHz to about 13.56 MHz. The coils and magnetic wires 252 may assist providing high RF energy to drive ions dissociated into certain depth of the substrate 151. As the RF power sources 240 and matching network 238 coupled to the showerhead 220 may provide similar functions to drive ion is mostly configured to dissociate ions from the processing gas, coils or magnetic wires 252 may assist providing a relatively higher power energy to drive dissociated ions into certain depth of the substrate 151 as needed. In the embodiment wherein the coils or magnetic wires 252 are not present in the processing system 232, the processing chamber 200 may then be configured as a conventional CVD processing chamber to deposit material layers as needed with implantation performed on the deposited film in a different chamber, such as the chamber 100 described above.

The controller 210 includes a central processing unit (CPU) 212, a memory 216, and a support circuit 214 utilized to control the process sequence and regulate the gas flows from the gas panel 230. The CPU 212 may be any form of general purpose computer processor that may be used in an industrial setting. The software routines can be stored in the memory 216, such as random access memory, read only memory, floppy, or hard disk drive, or other form of digital storage. The support circuit 214 is conventionally coupled to the CPU 212 and may include cache, clock circuits, input/output systems, power supplies, and the like. Bi-directional communications between the control unit 210 and the various components of the processing system 232 are handled through numerous signal cables collectively referred to as signal buses 218, some of which are illustrated in FIG. 2.

The above CVD system description is provided mainly for illustrative purposes, and other plasma processing chambers may also be employed for practicing embodiments of the invention.

FIG. 3 illustrates a process flow diagram of a method 300 for forming a hydrogen implanted amorphous carbon layer according to one embodiment of the present invention. FIGS. 4A-4C are schematic cross-sectional view illustrating a sequence for forming a hydrogen implanted amorphous carbon layer for use as a hardmask layer according to the method 300.

The method 300 begins at step 302 by providing a substrate 151 having a material layer 402 disposed thereon, as shown in FIG. 4A. The substrate 151 may have a substantially planar surface, an uneven surface, or a structure formed thereon. In one embodiment, the material layer 402 may be a part of a film stack utilized to form a gate structure, a contact structure, an interconnection structure or shallow trench isolation (STI) structure in the front end or back end processes. In embodiments wherein the material layer 402 is not present, the process 300 be directly formed in the substrate 151.

In one embodiment, the material layer 402 maybe a silicon layer utilized to form a gate electrode. In another embodiment, the material layer 402 may include a silicon oxide layer, a silicon oxide layer deposited over a silicon layer. In yet another embodiment, the material layer 402 may include one or more layers of other dielectric materials utilized to fabricate semiconductor devices. Suitable examples of the dielectric layers include silicon oxide, silicon nitride, silicon oxynitride, silicon carbide, or any suitable low-k or porous dielectric material as needed. In still another embodiment, the material layer 302 does not include any metal layers.

At step 404, an amorphous carbon layer 404 is formed on the material layer 402, as shown in FIG. 4B. The amorphous carbon layer 404 may be formed in a chemical vapor deposition (CVD) chamber, such as the CVD chamber depicted in FIG. 2. Alternatively, the amorphous carbon layer 404 may be deposited in any suitable deposition chamber, such a chemical vapor deposition (CVD), atomic layer deposition (ALD), cyclical layer deposition (CLD), physical vapor deposition (PVD), or the like as needed. In an exemplary embodiment depicted herein, the amorphous carbon layer 404 is formed in the CVD chamber 200 depicted in FIG. 2.

During deposition of the amorphous carbon layer 404, a gas mixture may be supplied into the processing chamber 200 for processing. The gas mixture includes at least a hydrocarbon compound and an inert gas. In one embodiment, hydrocarbon compound has a formula CₓH_{y}, where x has a range between 1 and 12 and y has a range of between 4 and 26. More specifically, aliphatic hydrocarbons include, for example, alkanes such as methane, ethane, propane, butane, pentane, hexane, heptane, octane, nonane, decane and the like; alkenes such as propene, ethylene, propylene, butylene, pentene, and the like; dienes such as hexadiene butadiene, isoprene, pentadiene and the like; alkynes such as acetylene, vinylacetylene and the like. Alicyclic hydrocarbons include, for example, cyclopropane, cyclobutane, cyclopentane, cyclopentadiene, toluene and the like. Aromatic hydrocarbons include, for example, benzene, styrene, toluene, xylene, pyridine, ethylbenzene, acetophenone, methyl benzoate, phenyl acetate, phenol, cresol, furan, and the like. Additionally, alpha-terpinene, cymene, 1,1,3,3-tetramethylbutylbenzene, t-butylether, t-butylethylene, methyl-methacrylate, and t-butylfurfurylether may be utilized. Additionally, alpha-terpinene, cymene, 1,1,3,3-tetramethylbutylbenzene, t-butylether, t-butylethylene, methyl-methacrylate, and t-butylfurfurylether may be selected. In an exemplary embodiment, the hydrocarbon compounds are propene, acetylene, ethylene, propylene, butylenes, toluene, alpha-terpinene. In a particular embodiment, the hydrocarbon compound is propene (C₃H₆) or acetylene.

Alternatively, one or more hydrocarbon compounds may be mixed with the hydrocarbon compound in the gas mixture supplied to the process chamber. A mixture of two or more hydrocarbon compounds may be used to deposit the amorphous carbon material.

The inert gas, such as argon (Ar) or helium (He), is supplied with the gas mixture into the process chamber 200. Other carrier gases, such as nitrogen (N₂) and nitric oxide (NO), hydrogen (H₂), ammonia (NH₃), a mixture of hydrogen (H₂) and nitrogen (N₂), or combinations thereof may also be used to control the density and deposition rate of the amorphous carbon layer. The addition of H₂ and/or NH₃ may be used to control the hydrogen ratio (e.g., carbon to hydrogen ratio) of the deposited amorphous carbon layer. The hydrogen ratio present in the amorphous carbon layer provides control over layer properties, such as reflectivity, transparency and density.

In one embodiment, an inert gas, such as argon (Ar) or helium (He) gas, is supplied with the hydrocarbon compound, such as propene (C₃H₆) or acetylene, into the process chamber to deposit the amorphous carbon layer. The inert gas provided in the gas mixture may assist control of the optical and mechanical properties of the as-deposited layer, such as the index of refraction (n) and the absorption coefficient (k), hardness, density and elastic modulus of the amorphous carbon layer 404.

In one embodiment, the absorption coefficient (k) of the deposited amorphous carbon layer may be controlled between about 0.2 and about 1.8 at a wavelength about 633 nm, and between about 0.4 and about 1.3 at a wavelength about 243 nm, and between about 0.3 and about 0.6 at a wavelength about 193 nm. The amorphous carbon layer 404 may have a thickness 408 between about 10 nm and about 300 nm.

During deposition, a relatively higher RF source power greater than 400 Watts may be utilized to deposit the amorphous carbon layer 404. The high RF power utilized to deposit the amorphous carbon layer 404 may assist forming the amorphous carbon layer 404 with high density. Furthermore, relatively low process pressure, for example, less than 20 mTorr, may also be utilized to form the high density amorphous carbon layer 404. It is believed that higher RF power utilized during the deposition process may provide higher ion bombardment that may enhance dissociation of the ions from the gas mixture. However, excess carbon elements cramped into each lattice unit not only increases film density, but also adversely results in high stress and film opaqueness. Accordingly, a hydrogen ion implantation process may be performed after the deposition process at step 304 to assist lowering film stress as well as maintaining film density and transparency, which will be described further below at step 306.

During deposition, the substrate temperature may be controlled between about 300 degrees Celsius and about 800 degrees Celsius. The hydrocarbon compound, such as propene (C₃H₆), may be supplied in the gas mixture at a rate between about 200 sccm and about 3000 sccm, such as between about 400 sccm and about 2000 sccm. The inert gas, such as Ar gas, may be supplied in the gas mixture at a rate between about 200 sccm and about 10000 sccm, such as about 1200 sccm and about 8000 sccm. A RF source power of between about 400 Watts to about 2000 Watts, such as 450 Watts to about 1000 Watts may be applied to maintain a plasma formed from the gas mixture. The process pressure may be maintained at about 1 Torr to about 20 Torr, such as about 2 Torr and about 12 Tarr, for example, about 4 Torr to about 9 Torr. The spacing between the substrate and showerhead may be controlled at about 200 mils to about 1000 mils.

At step 306, after the amorphous carbon layer 404 is formed on the substrate 151, a hydrogen implantation process is performed on the amorphous carbon layer 404. The hydrogen implantation process implants hydrogen ions into the amorphous carbon layer 404, forming a hydrogen implanted amorphous carbon layer 406, as shown in FIG. 4C. The hydrogen ions implanted into the amorphous carbon layer 404 may assist breaking portion of the carbon bonding in the amorphous carbon layer 404 to insert hydrogen elements between the carbon bonding.

In one embodiment, the hydrogen implantation process may be ex-situ performed at a plasma ion implantation chamber, such as the chamber 100 depicted in FIG. 1, after the amorphous carbon layer 404 is deposited by the CVD chamber 232 depicted in FIG. 2. Alternatively, the hydrogen implantation process may be ex-situ using a suitable ion beam/ion gun implantation tool. In another embodiment, hydrogen implantation process may be in-situ performed in the CVD chamber 232 depicted in FIG. 2 equipped with plasma ion implantation device 251 to perform an ion implantation process on the substrate 151 after the amorphous carbon deposition process at step 304. In this particular embodiment, the hydrogen implantation process may be performed in-situ with the amorphous carbon layer deposition process at step 304 under vacuum (e.g., without breaking vacuum) without removing the substrate 151 from the CVD chamber 232. The CVD chamber 232 and the plasma ion implantation chamber 100 may be incorporated in a cluster tool so that the substrate being processed in these two chambers is not exposed to atmosphere or an ambient environment, so that the method 300 is performed completely under vacuum (e.g., without breaking vacuum).

During the hydrogen implantation process, the hydrogen ions dissociated in the processing chamber are directed toward the substrate 151, and impinge into the amorphous carbon layer 404 to form the hydrogen implanted amorphous carbon layer 406. The dissociated hydrogen ions will begin to disrupt and change the film properties when the ion implantation energy and the dissociated hydrogen ions reach sufficient intensity to stimulate thermal motion of the atoms in the amorphous carbon layer 404. The ions implanted into the amorphous carbon layer 404 will substantially change the bonding structures and/or the bonding energy of the carbon bonds in the amorphous carbon layer 404. Prior to the hydrogen ion implantation process, the carbon elements bonded in the amorphous carbon layer 404 may mostly form in sp3 hybridized carbons with four single bonds pointing towards the corner of a tetrahedron. Some sp2 hybridized carbons with two single and one double bond, e.g., the three bonds pointing towards the corners of a triangle, may also be found in the amorphous carbon layer 404. The amount of hydrogen termination bonds and the extents of any missing or dangling carbon bonds included in the sp3 hybridized carbons or sp2 hybridized carbons affect how tightly these carbon atoms are networked and packed, thus determining film density and stress. In an extreme example wherein the amorphous carbon layer 404 is formed with complete sp3 hybridization and zero hydrogen content when all carbon atoms are fully interconnected, a density greater than 1.6 g/cc may be achieved. However, under this extreme example, the stress may also reach up to several GPa, which is undesired as it may cause substrate bow or depth of focus issue during the subsequent lithography process. Therefore, when the carbon bonding structures are severely constrained, it may adversely contribute to high film stress even though the density of the film is increased. Therefore, a hydrogen implantation process 300 is performed to break a portion of the carbon bonds and terminate these bonds with hydrogen atoms. By doing so, as the hydrogen atoms are incorporated into the carbon bonds, while the amount of carbon remains substantially the same in the hydrogen implanted amorphous carbon layer 406. For example, the density of the hydrogen implanted amorphous carbon layer 406 may remain substantially the same, such as greater than 1.6 g/cc while desirably maintaining the stress of the hydrogen implanted amorphous carbon layer 406 at a low level, such as less than 800 mega-pascal (MPa) compressive, such as between about 800 mega-pascal (MPa) compressive and about 100 mega-pascal (MPa) compressive. Other film properties, such as film transparency, are remained substantially the same. In one embodiment, the absorption coefficient (k) of the hydrogen implanted amorphous carbon layer 406 may be controlled between about 0.2 and about 1.8 at a wavelength about 633 nm, and between about 0.4 and about 1.3 at a wavelength about 243 nm, and between about 0.3 and about 0.6 at a wavelength about 193 nm. The hydrogen ions may be implanted at a concentration of between about 10¹⁵ atoms/cm³ and about 10¹⁷ atoms/cm³ atoms/cm³ in the hydrogen implanted amorphous carbon layer 406. The hydrogen implanted amorphous carbon layer 406 may have a density greater than 1.6 g/cc, such as between about 1.7 g/cc and about 2.0 g/cc and a film stress less than 800 mega-pascal (MPa) compressive, such as between about 800 mega-pascal (MPa) compressive and about 100 mega-pascal (MPa) compressive.

Accordingly, by choosing a proper range of ion implantation energy to implant suitable amount of hydrogen ions into the amorphous carbon layer 404, the hydrogen implanted carbon layer 406 with desired film properties may be obtained.

In one embodiment, suitable examples of the implantation gas mixture include hydrogen containing gas, such H₂, NH₃, H₂O and the like. In some cases, inert gas, such as He or Ar, may be used as the implantation gas mixture. In one embodiment, the ions dissociated from the gas mixture may be implanted into through the bulk thickness 408 of the amorphous carbon layer 404, or at least about 50 percent to about 90 percent of the overall thickness 408 of the amorphous carbon layer 404. In one embodiment, the bulk thickness 408 of the amorphous carbon layer 404 is between about 10 nm and about 300 nm.

In addition to the hydrogen containing gas, an inert gas may also be supplied with the hydrogen containing gas during the implantation process as needed. Suitable examples of the inert gas include N₂, Ar, He Xe, Kr and the like. The inert gas may promote the ion bombardment in the gas mixture, thereby increasing the probability of process gas collision, thereby resulting in reduced recombination of ion species.

In one embodiment, the ion implanting gas mixture, such as H₂, may be supplied into the processing chamber during implantation at a flow rate between about 20 sccm and about 2000 sccm. The chamber pressure is generally maintained between about 2 mTorr and about 20 mTorr, such as about 8 or mTorr.

RF power, such as capacitive or inductive RF power, DC power, electromagnetic energy, or magnetron sputtering, may be supplied into the processing chamber 100 to assist dissociating the gas mixture during processing. Ions generated by the dissociative energy may be accelerated toward the substrate using an electric field produced by applying a DC or RF electrical bias to the substrate support or to a gas inlet above the substrate support, or both. In some embodiments, the ions may be subjected to a mass selection or mass filtration process, which may comprise passing the ions through a magnetic field aligned orthogonal to the desired direction of motion. The electric field provided by the RF power may be capacitively or inductively coupled for purposes of ionizing the atoms, and may be a DC discharge field or an alternating field, such as an RF field. Alternately, microwave energy may be applied to the ion implanting gas mixture containing any of these elements to generate ions. In some embodiments, the gas containing energetic ions may be a plasma. An electrical bias (peak to peak voltage) of between about 5000 V and about 9900 V, such as about 9000V is applied to the substrate support, the gas distributor, or both, to accelerate the ions toward the substrate surface with the desired energy. In some embodiments, the electrical bias is also used to ionize the ion implantation processing gas. In other embodiments, a second electric field is used to ionize the process gas. In one embodiment, a high-frequency RF field and a low-frequency RF field are provided to ionize the ion implantation processing gas and bias the substrate support. The high-frequency field is provided at a frequency of 13.56 MHz and a power level between about 200 W and about 5,000 W, and the low-frequency field is provided at a frequency between about 1,000 Hz and about 10 kHz at a power level between about 50 W and about 200 W. Energetic ions may be generated by an inductively coupled electric field by providing a recirculation pathway through an inductive coil powered by RF power between about 50 W and about 500 W. The ions thus produced will generally be accelerated toward the substrate by biasing the substrate or a gas distributor as described above.

In some embodiments, generations of ions may be pulsed. Power may be applied to the plasma source for a desired time, and then discontinued for a desired time. Power cycling may be repeated for a desired number of cycles at a desired frequency and duty cycle. In many embodiments, the plasma may be pulsed at a frequency between about 0.1 Hz and about 1,000 Hz, such as between about 10 Hz and about 500 Hz. In other embodiments, the plasma pulsing may proceed with a duty cycle (ratio of powered time to unpowered time per cycle) between about 10% and about 90%, such as between about 30% and about 70%. In one embodiment, the RF source power may be supplied at between about 300 Watts to about 2000 Watts and the bias power may be supplied at between about 2000 Watts and about 5000 Watts.

In another embodiment, the amorphous carbon layer deposition process at step 304 and the ion implantation process at step 306 may be repeatedly performed, as indicated by loop 308 in FIG. 3, to incrementally increase the overall thickness of the hydrogen implanted amorphous carbon layer until a desired thickness is obtained, as further described with referenced to Figured 5A-5E. Similar to the method 300 described in FIG. 3 and embodiment depicted in FIGS. 4A-4C. An amorphous carbon deposition process of step 304 is performed to form a first amorphous carbon layer 502 on the material layer 402 on the substrate, as depicted in FIG. 5A. The first amorphous carbon layer 502, in this embodiment, may have a thickness between about 10 nm and about 100 nm, as multiple layers of amorphous carbon layer will be later stacked on the amorphous carbon layer 502 in the following steps. Subsequently, a hydrogen implantation process of step 306 may be performed to implant hydrogen atoms into the first amorphous carbon layer 502, forming a first hydrogen implanted amorphous carbon layer 506, as shown in FIG. 5B. After the ion implantation process, the first hydrogen implanted amorphous carbon layer 506 may be a thickness between about 10 nm and about 300 nm. Subsequently, as indicated by the loop 308, the amorphous carbon deposition process of step 304 and the hydrogen implantation process of step 306 may be repeatedly performed to form a second amorphous carbon layer 508 and a second hydrogen implanted amorphous carbon layer 510 on the first hydrogen implanted amorphous carbon layer 506, as shown in FIGS. 5C-5D. As discussed above, the amorphous carbon deposition process of step 304 and the hydrogen implantation process of step 306 may be continuously performed and cycled until a desired thickness 517 of multiple hydrogen implanted amorphous carbon layers 506, 510, 512, 514 are formed on the substrate 151, forming a bulk hydrogen treated amorphous carbon layer 516 including hydrogen implanted amorphous carbon layers formed from different cycles of deposition and implantation process. Though only four layers of hydrogen implanted amorphous carbon layers 506, 510, 512, 514 are shown in FIG. 5E, it is noted that numbers of layers of the hydrogen implanted amorphous carbon layers 506, 510, 512, 514 formed on the substrate 151 may be varied and formed as many as needed.

The method 300 is particularly useful for the process used in the front end process (FEOL) prior to metallization process in a semiconductor device manufacturing process. The hydrogen implanted amorphous carbon layer serves as an hardmask layer during an etching process. Suitable front end process (FEOL) includes gate manufacturing applications, contact structure applications, shallow trench isolation (STI) process, and the like. In the embodiments wherein and the hydrogen amorphous carbon layer 406 and the hydrogen implanted amorphous carbon layer 516 may also be used as an etch stop layer or used as different films for different process purposes, the mechanical or optical properties of the film may be adjusted as well to meet the particular process need.

Thus, a method for forming a hydrogen implanted amorphous carbon layer having both desired density and optical film properties with low stress are provided. The method advantageously improves the mechanical properties, such as low stress and high density, of the hydrogen implanted amorphous carbon. The improved mechanical properties of the carbon layer provides high film selectivity and quality for the subsequent etching process while maintaining desired range of the film flatness and film optical properties, such as index of refraction (n) and the absorption coefficient (k), for the subsequent lithography process.

While the foregoing is directed to embodiments of the present invention, other and further embodiments of the invention may be devised without departing from the basic scope thereof, and the scope thereof is determined by the claims that follow.

What is claimed is:

1. A method of forming a hydrogen implanted amorphous carbon layer, comprising:
(a) providing a substrate having a material layer disposed thereon;
(b) forming an amorphous carbon layer on the material layer; and
(c) ion implanting hydrogen ions from a hydrogen containing gas into the amorphous carbon layer to form a hydrogen implanted amorphous carbon layer.

2. The method of claim 1, further comprising:
repeatedly performing step (b)-(c) until a desired thickness of the hydrogen implanted amorphous carbon layer is reached.

3. The method of claim 2, wherein the hydrogen implanted amorphous carbon layer has the desired thickness between about 10 nm and about 300 nm.

4. The method of claim 1, wherein ion implanting hydrogen ions into the amorphous carbon layer further comprises:
applying an RF source power to plasma implant hydrogen ions into the amorphous carbon layer.

5. The method of claim 1, wherein ion implanting hydrogen ions into the amorphous carbon layer further comprises:
using at least one of an ion gun or an ion beam to implant hydrogen ions into the amorphous carbon layer.

6. The method of claim 1, wherein the step (b) and step (c) are formed in-situ in a processing chamber without breaking vacuum.

7. The method of claim 1, wherein the step (b) and step (c) are formed ex-situ in different processing chambers incorporated in a cluster tool.

8. The method of claim 1, wherein the hydrogen implanted amorphous carbon layer has a film density greater than 1.6 g/cc.

9. The method of claim 1, wherein the hydrogen implanted amorphous carbon layer has a film stress less than less than 800 mega-pascal (MPa) compressive.

10. The method of claim 1, wherein the hydrogen implanted amorphous carbon layer serves as a hardmask layer in an etching process.

11. The method of claim 1, wherein ion implanting hydrogen ions into the amorphous carbon layer further comprises:
applying a bias RF power to the substrate.

12. The method of claim 4, wherein the RF source power is between about 300 Watts and about 2000 Watts.

13. The method of claim 11, wherein the RF bias power is between about 2000 Watts and about 5000 Watts.

14. The method of claim 1, wherein the material layer is selected from a group consisting of silicon oxide, silicon nitride, silicon oxyntride, silicon carbide, low-k and porous dielectric material.

15. A method of a hydrogen implanted amorphous carbon layer, comprising:
(a) providing a substrate having a material layer disposed thereon;
(b) forming an amorphous carbon layer on the material layer; and
(c) ion implanting hydrogen ions from a hydrogen containing gas into the amorphous carbon layer to form a hydrogen implanted amorphous carbon layer, wherein the hydrogen implanted amorphous carbon layer has a stress between about 800 mega-pascal (MPa) compressive and about 100 mega-pascal (MPa) compressive.

16. The method of claim 15, wherein ion implanting hydrogen ions into the amorphous carbon layer further comprises:
applying an RF source power to plasma implant hydrogen ions into the amorphous carbon layer.

17. The method of claim 15, wherein ion implanting hydrogen ions into the amorphous carbon layer further comprises:
using at least one of an ion gun or an ion beam to implant hydrogen ions in to the amorphous carbon layer.

18. The method of claim 15, wherein the hydrogen implanted amorphous carbon layer has a film density greater than 1.6 g/cc.

19. The method of claim 15, further comprising:
using the hydrogen implanted amorphous carbon layer serves as a hardmask layer in an etching process.

20. A method of a hydrogen implanted amorphous carbon layer, comprising:
(a) providing a substrate having a material layer disposed thereon;
(b) forming an amorphous carbon layer on the material layer; and
(c) ion implanting hydrogen ions from a hydrogen containing gas into the amorphous carbon layer to form a hydrogen implanted amorphous carbon layer; and
(d) etching the material layer using the hydrogen implanted amorphous carbon layer as a hardmask layer.
